(19) United States
(12) Patent Application Publication
(10) Pub. No.: US 2009/0294975 A1
(43) Pub. Date: Dec. 3, 2009

(54) Package for a Die

(76) Inventors: Eamonn Gilmartin, Leeds (GB); Stephane David, Leeds (GB)

Correspondence Address: HOWARD & HOWARD ATTORNEYS PLLC, 450 West Fourth Street, Royal Oak, MI, 48067, US

(21) Appl. No.: 11/989,270

(22) PCT Filed: Jul. 24, 2006
(86) PCT No.: PCT/GB2006/002761

§ 371 Date: Jul. 15, 2009

(30) Foreign Application Priority Data
Jul. 23, 2005 (GB) 0515219.4

(51) Int. Cl. H01L 23/051

(52) U.S. Cl. 257/773; 257/E23.187; 257/692

(57) ABSTRACT

A package for a die comprising
a thermally conducting carrier;
a dielectric frame on the carrier, the frame having a recess therein for receiving a die;
an electrically insulating lid adapted to be positioned on the frame to cover the recess, the lid having dimensions such that when covering the recess a portion of the lid extends beyond the frame creating at least one overhang;
the frame having at least one electrically conducting frame path; and
the lid having a corresponding electrically conducting lid path arranged such that when the lid is positioned on the frame a portion of the lid path overlies the frame path, the lid path extending onto the overhang beyond the frame.

The present invention relates to a package for a die. More particularly, but not exclusively, the present invention relates to a package comprising a carrier, a frame on the carrier having a recess for a die and a lid on the frame.

Power packages for RF applications are known. Such packages typically comprise a die on a carrier covered by a lid. In use the package is placed on a printed circuit board (PCB) or in a cavity in a PCB and connections made between the die inside the package and the PCB. A number of methods of making this connection are known including the use of gullwings, dielectric tabs, ball arrays or castellations. Such methods however tend to be either expensive to manufacture or electrically and mechanically unreliable.

Accordingly, in a first aspect the present invention provides a package for a die comprising
a thermally conducting carrier;
a dielectric frame on the carrier, the frame having a recess therein for receiving a die;
an electrically insulating lid adapted to be positioned on the frame to cover the recess, the lid having dimensions such that when covering the recess a portion of the lid extends beyond the frame creating at least one overhang;
the frame having at least one electrically conducting frame path; and
the lid having a corresponding electrically conducting lid path arranged such that when the lid is positioned on the frame a portion of the lid path overlies the frame path, the lid path extending on to the overhang beyond the frame.

The package according to the invention is inexpensive and relatively straightforward to manufacture. It is also reliable.

The frame path can extend from proximate to the recess outwardly towards the frame edge.

The package can comprise a plurality of electrically conducting frame paths.

Preferably the package comprises a plurality of electrically conducting lid paths, each lid path being arranged such that when the lid is positioned on the frame each lid path is in electrical contact with a corresponding frame path.

The carrier can be a metal.

Preferably at least one of the carrier and frame can comprise a positioning element for positioning the lid with respect to the frame.

Preferably the lid comprises a further positioning element.

The package can further comprise a die within the recess, the package preferably further comprising at least one electrically conducting bridge extending between the die and at least one frame path.

The frame can comprise a plurality of recesses for receiving a plurality of dies.

The lid can be grounded.

In a further aspect of the invention there is provided a printed circuit board comprising a recess and a package for a die within the recess, the package for a die comprising
a thermally conducting carrier;
a dielectric frame on the carrier, the frame having a recess therein for receiving a die;
an electrically insulating lid adapted to be positioned on the frame to cover the recess, the lid having dimensions such that when covering the recess a portion of the lid extends beyond the frame creating at least one overhang;
the frame having at least one electrically conducting frame path; and
the lid having a corresponding electrically conducting lid path arranged such that when the lid is positioned on the frame a portion of the lid path abuts the frame path making an electrical contact therebetween, the lid path extending on the overhang beyond the frame.

The present invention will now be described by way of example only and not in any limitative sense with referenced to the accompanying drawings in which

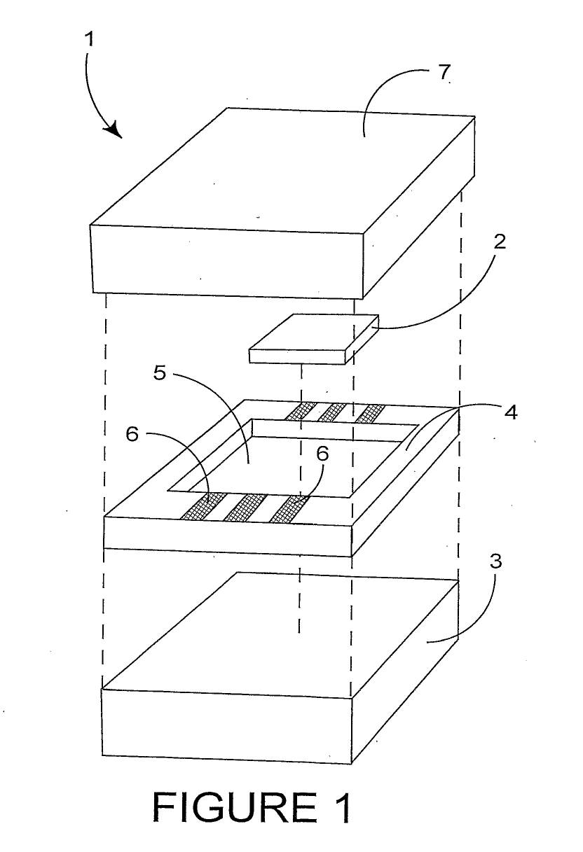

FIG. 1 shows, in perspective view, a package for a die according to the invention;

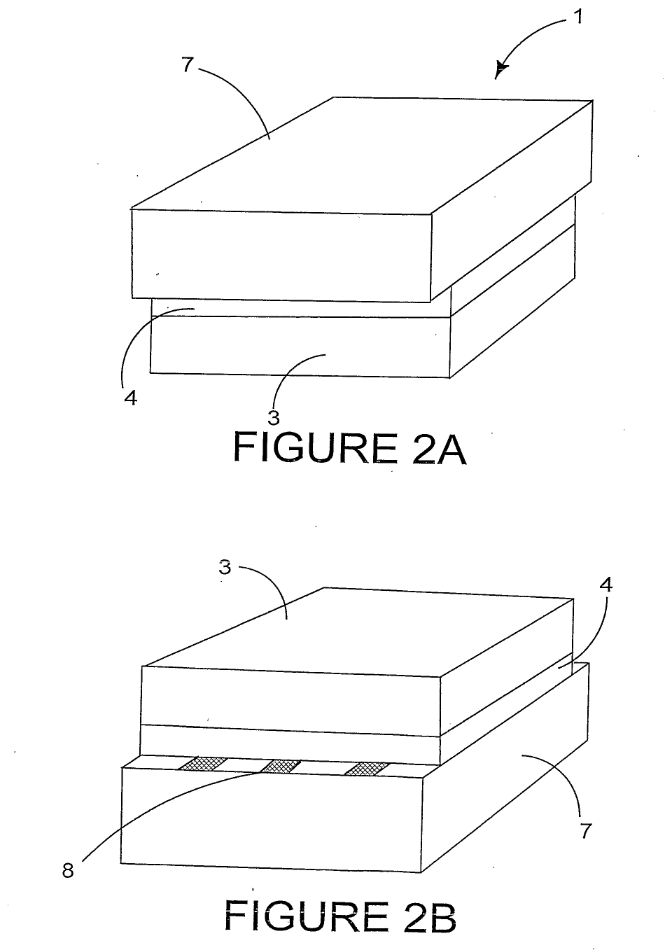

FIG. 2 shows the assembled package from both above and below;

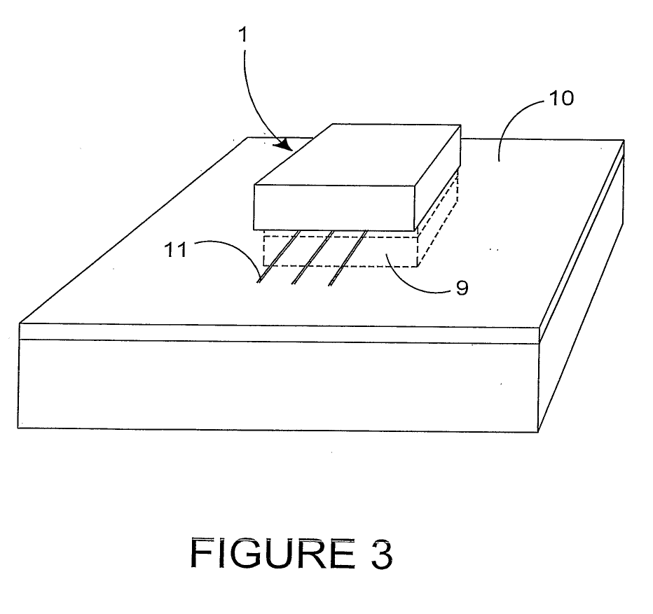

FIG. 3 shows the package within a recess in a PCB according to the invention; and

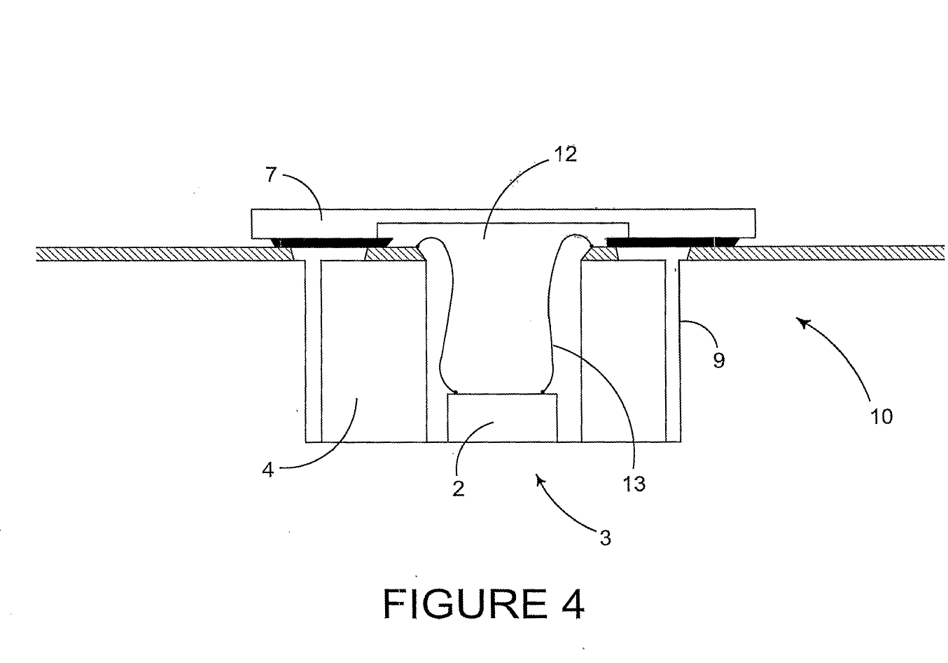

FIG. 4 shows, in cross section, a further embodiment of a package according to the invention.

Shown in FIG. 1, in exploded view, is a package for a die 1 according to the invention, including the die 2. The package 1 comprises a thermally conducting carrier 3. The carrier 3 of this embodiment is copper. In other embodiments other thermally conducting materials such as CuW, Al or CuMo are possible. Optionally the carrier is gold plated.

Laminated to the carrier by an epoxy (not shown) is a frame 4. The frame 4 is an electrically insulating dielectric material. The frame 4 of this embodiment is a ceramic. In alternative embodiments the frame 4 can be a PTFE such as Duroid® or R04350. In alternative embodiments the frame 4 can be soldered to the carrier 3.

The frame 4 comprises a cavity 5 which extends down to the carrier 3. Positioned within the cavity 5 and attached to the carrier 3 is the semiconductor die 2. When in use the die 2 generates heat which is carried away by the carrier 3. The die 2 can be connected to the carrier 3 either before or after the frame 4.

Positioned on the top face of the frame 4 are a plurality of electrically conducting frame paths 6 as shown. Each of the frame paths 6 extends from proximate to the recess 5 outwards towards the frame edge.

Once both the frame 4 and die 2 are connected to the carrier 3 the die 2 is electrically connected to the frame paths 6 by traditional bond wires (not shown). The die 2 can be tested at this point if required.

The package 1 further comprises an electrically insulating lid 7. On the underside of the lid 7 are a plurality of electrically conducting lid paths 8. The lid 7 is positioned on the frame 4. When correctly positioned the lid 7 covers the recess 5, and the lid paths 8 and frame paths 6 line up forming electrical connections between the two. In this embodiment the lid 7 is attached to the frame 4 by an electrically conducting material (not shown) applied to the lid and frame paths 6, 8 to improve the electrical connection between the two.

In an alternative embodiment (not shown) the frame 4 and lid 7 both include metal guiding tags. Overlying the guiding tag on the lid 7 on the guiding tag on the frame 4 ensures the lid 7 is correctly position with respect to the frame 4. Further adhesive can be added to the tags to improve the strength of the joint between lid 7 and frame 4. If guide tags are used the adhesive between the frame paths 6 and lid paths 8 is optional. Electrical contact between the two may be achieved by the paths 6, 8 being mechanically urged into contact.

In a further embodiment (not shown) the lid 7 is connected to the frame 4 by mechanical means such as snap fit engagement means.

Shown in FIGS. 2a and 2b is the assembled package 1, both from above and below. As can be seen, the lid 7 is dimensioned to be slightly larger than the frame 4 and carrier 3 such that it overhangs the frame 4 and carrier 3. The lid paths 8 extend out onto the overhang as shown.

Shown in FIG. 3 in perspective view is the package 1 sited within a cavity 9 of a printed circuit board 10. The depth of the cavity 9 corresponds to the total height of carrier 3 and frame 4 such that the top surface of the frame 4 is at the same level as the top surface of the PCB 10. The portion of the lid paths 8 on the overhang act as electrical bridges between the frame paths 6 (and hence the die 2) and electrically conducting paths 11 on the PCB 10 as shown.

The electrical connections between the package 1 and the PCB 10 are integrated into the lid 7 and are covered and protected by the lid 7. The connectors are therefore far more robust and reliable then tabs or laminated pins. They are also simpler to manufacture.

Shown in FIG. 4 in cross section is a further embodiment of this invention. In this embodiment the die 2 and frame 4 are connected directly to the base of the recess 9 in the PCB 10. The base of the recess 9 acts as the carrier 3 conducting heat away from the semiconductor die 2. The lid 7 has a recess 12 in its underside to allow further room for the connection between the conducting paths 6 on the frame 4 and the connecting wires 13 to the die 2.

In a further embodiment the frame comprises a plurality of recesses, each adapted to receive at least one die.

In an alternative embodiment the lid is grounded.

In an alternative embodiment the die is not connected directly to the conducting path on the frame but to a chip capacitor which is in turn connected to the frame conducting path.

1. A package for a die comprising:
a thermally conducting carrier;
a dielectric frame on the carrier, the frame having a recess therein for receiving a die;
an electrically insulating lid adapted to be positioned on the frame to cover the recess, the lid having dimensions such that when covering the recess a portion of the lid extends beyond the frame creating at least one overhang;
the frame having at least one electrically conducting frame path; and
the lid having a corresponding electrically conducting lid path arranged such that when the lid is positioned on the frame a portion of the lid path overlies the frame path, the lid path extending onto the overhang beyond the frame.

2. A package as claimed in claim 1, wherein the frame path extends from proximate to the recess outwardly towards the frame edge.

3. A package as claimed in claim 1, comprising a plurality of electrically conducting frame paths.

4. A package as claimed in claim 3, comprising a plurality of electrically conducting lid paths, each lid path being arranged such that when the lid is positioned on the frame each lid path is in electrical contact with a corresponding frame path.

5. A package as claimed in claim 1 4, wherein the carrier is a metal.

6. A package as claimed in claim 1, wherein at least one of the carrier and frame comprises a positioning element for positioning the lid with respect to the frame.

7. A package as claimed in claim 6, wherein the lid comprises a further positioning element.

8. A package as claimed in claim 1, further comprising at least one electrically conducting bridge extending from the frame path for connection to the die within the recess.

9. A package as claimed in claim 1, wherein the frame comprises a plurality of recesses for receiving a plurality of dies.

10. A package as claimed in claim 1, wherein the lid is grounded.

11-13. (canceled)
